(19) United States
(12) Patent Application Publication
(10) Pub. No.: US 2009/0206402 A1
(43) Pub. Date: Aug. 20, 2009

(54) Lateral Trench MOSFET with Bi-Directional Voltage Blocking

(75) Inventor: Donald Ray Disney, Cupertino, CA (US)

Correspondence Address: ADVANCED ANALOGIC TECHNOLOGIES, 3230 Scott Blvd, Santa Clara, CA, 95054, US

(73) Assignee: ADVANCED ANALOGIC TECHNOLOGIES, INC., Sunnyvale, CA (US)

(21) Appl. No.: 12/032,247

(22) Filed: Feb. 15, 2008

(51) Int. Cl. H01L 27/088

(52) U.S. Cl. 257/337; 257/343; 257/E27.06

(57) ABSTRACT

A lateral trench DMOS device formed in a substrate of a first conductivity type includes a trench extending downward from a surface of the substrate, the trench lined with a dielectric layer and containing a gate electrode. The device includes a source region of a second conductivity type adjacent the surface of the substrate and a sidewall of the trench, a drain region of the second conductivity type adjacent the surface of the substrate and spaced apart from the source region, a body region of the first conductivity type adjacent the source region and the sidewall of the trench, a drift region of the second conductivity type adjacent the body region, the sidewall of the trench and the drain region; and a body contact region of the first conductivity type disposed in the body region and spaced apart from the source region.

### BACKGROUND OF THE INVENTION

Lateral Trench MOSFET (LTDMOS) devices are power semiconductor devices that may be integrated with control circuitry to form monolithic power integrated circuits (ICs) used in a wide range of applications, including power management ICs. LTDMOS devices consist of large trench areas that are oxidized and filled with polysilicon (poly). The poly forms the gate electrode of the LTDMOS, the oxide layer forms the gate oxide, and channel regions are formed on the sidewalls of the silicon trenches. Current generally flows vertically through the channel regions, then laterally through a drift region.

Prior art LTDMOS devices offer only one-directional blocking, e.g. they can block a high drain-to-source voltage (V_{DS}), but cannot support any significant source-to-drain voltage (V_{SD}). For some applications, such as over-voltage protected battery chargers, it is preferable to have an LTDMOS device that can block a high V_{DS}, e.g. 20V-60V, but can also block a lower V_{SD}, e.g. 5-10V, in order to prevent current flow from source to drain under fault conditions. Prior art battery chargers provide this protection by including series power devices. Unfortunately, inclusion of a series power device increases overall resistance and generally decreases circuit efficiency.

Therefore, a goal of this invention is to provide improved LTDMOS device designs and that are capable of blocking voltage in both directions. In a preferred embodiment, the blocking voltage is significantly higher in one direction than in the other direction.

### SUMMARY OF THE INVENTION

An embodiment of the present invention provides a lateral trench MOFSFET (LTDMOS) device capable of blocking voltage in both directions. The device is preferably asymmetric blocking a high V_{DS} (e.g., 20V-60V) and a lower V_{SD}, (e.g., 5-10V). To provide asymmetric blocking, a LTDMOS device is fabricated in a P-type semiconductor substrate. A gate is formed by etching a trench in the substrate, depositing a gate dielectric layer on the sidewalls of the trench and refilling the trench with a conductive gate. Two field oxide regions are formed on the surface of substrate: a proximal oxide region that is positioned on the portion of the surface that is near the trench and a distal oxide region that is further from the trench.

An N-type drift region is formed in the substrate by high-energy implantation through the two field oxide regions. The drift region has a profile that is conformal to the thickness of the field oxide regions. A P-body region is formed in the drift region adjacent to the gate dielectric. The proximal oxide region partially overlays a portion of the P-body region. A heavily-doped N+ source region and a heavily-doped P+ body contact region are formed in the P-body region. The N+ source region is adjacent to the gate dielectric. The P+ body contact region is separated from the N+ source region at a distance determined by the width of the proximal field oxide region that partially overlies the P-body region. A heavily-doped N+ drain region is formed in the drift region and separated the from P-body region by the width of the distal field oxide region. Electrodes are formed for the source, drain and body regions.

The separation between the P+ body contact region and the N+ source region is not found in prior art LTDMOS devices and provides the benefit of allowing this LTDMOS device to support a voltage from the source electrode to the body electrode and drain electrode. The maximum voltage that can be supported from the drain to body and source is determined by the length and doping of the drift region, while the maximum voltage that can be supported from the source to the body is determined by the doping of the P-body and the separation between the P+ body contact region and the N+ source region.

A second embodiment of the present invention is another lateral trench MOFSFET (LTDMOS) device that provides asymmetric blocking a high V_{DS} (e.g., 20V-60V) and a lower V_{SD}, (e.g., 5-10V). To provide asymmetric blocking, this embodiment is fabricated as a low-voltage NMOS device in series with an LTDMOS device. Specifically, a P-type semiconductor substrate is used. A gate for the LTDMOS device is formed by etching a trench in the substrate, depositing a gate dielectric layer on the sidewalls of the trench and refilling the trench with a conductive gate. A field oxide region is formed on the surface of substrate.

An N-type drift region is formed in the substrate by high-energy implantation through the field oxide region. The drift region has a profile that is conformal to the thickness of the field oxide regions.

A P-body region is formed in the drift region adjacent to the gate dielectric. The low-voltage NMOS transistor is formed within the P-body region. Specifically, a heavily-doped N+ source region and a heavily-doped N+ drain region are formed within the P-body region for the low-voltage NMOS. An NMOS gate and an NMOS gate dielectric are formed on the surface of the of P-body region over and between the NMOS source region and the NMOS drain region A heavily-doped N+ source region and a heavily-doped P+ body contact region are formed for the LTDMOS device within the P-body region. The LTDMOS body region is adjacent to the NMOS source region and the LTDMOS source region is adjacent to the LTDMOS body region. An intermediate electrode connects the LTDMOS source, NMOS source and LTDMOS body regions. A drain electrode is formed in contact with the LTDMOS drain and a source electrode is formed in contact with the NMOS drain.

In the forward blocking state, the gate voltage is held low, such that both the NMOS and LTDMOS devices are off. The voltage from the drain electrode to the source electrode is supported by the reverse-biased junctions of the drift region, the P-body and the substrate. In the reverse blocking state, the gate voltage is also held low, and the voltage from source to drain is blocked by the reverse-biased junction of the NMOS drain and the P-body. In the on-state, the gate voltage is high enough to exceed the threshold voltage and form -conduction channels beneath the NMOS gate and adjacent the LTDMOS gate. Thus a continuous path exists for electron current to flow from the NMOS drain through the NMOS channel to the NMOS source through the intermediate electrode to the LTDMOS source, down through the LTDMOS, then laterally through the drift region to the LTDMOS drain.

### BRIEF DESCRIPTION OF THE DRAWINGS

FIG. 1 is a cross-section of a prior art LTDMOS with one-direction blocking capability.

FIG. 2 is a cross-section of an LTDMOS device according to an embodiment of the present invention with asymmetrical bi-directional blocking.

FIG. 3 is a Cross-section of an LTDMOS device according to an embodiment of the present invention with asymmetrical bi-directional blocking.

### DETAILED DESCRIPTION OF THE PREFERRED EMBODIMENTS

FIG. 1 shows a prior art Lateral Trench MOSFET (LTDMOS) from U.S. patent application Ser. No. 11/982,764 entitled “High-Voltage Bipolar-CMOS-DMOS Integrated Circuit Devices and Modular Methods of Forming the Same”, which is incorporated herein by reference. This LTDMOS is formed in a P-type semiconductor substrate 101. The gate 108 of the LTDMOS is formed by etching a trench in the substrate 101, forming a gate dielectric layer 107 on the sidewalls of the trench, and refilling the trench with a conductive gate 108. In a preferred embodiment, the gate dielectric 107 comprises a thermal silicon dioxide layer with thickness in the range of 100 to 500 angstroms, and the gate 108 comprises heavily-doped polysilicon. A field oxide region 109 is formed on the surface of substrate 101. N-type drift region 102 is formed by high-energy implantation through field oxide 109, forming a profile that is conformal to the thickness of the field oxide 109 (i.e. the portion of drift region 102 implanted through field oxide 109 is shallower than the portion of drift region 102 that is implanted directly into substrate 101). P-body region 103 is formed adjacent gate dielectric 107, preferably by high-energy implantation at multiple energies to tailor the doping profile to achieve the desired LTDMOS electrical characteristics, such as threshold voltage and prevention of punch-through. In this prior art example, P-body region 103 is implanted at an energy that is low enough such that the implant is essentially blocked by field oxide 109. Heavily-doped N+ drain region 104 is formed in drift region 102 and separated from P-body 103 by field oxide 109. Heavily-doped N+ source region 105 is formed in P-body 103 adjacent gate dielectric 107. Heavily-doped P+ body contact region 106 is formed in P-body 103 to provide ohmic contact to the P-body region and to prevent activation of the NPN parasitic transistor formed by drift region 102, P-body region 103, and source region 105. Interlevel dielectric (ILD) 110 covers the LTDMOS and has contact holes that allow topside contact by drain electrode 111 and source/body electrode 112.

In the off-state, this prior art LTDMOS supports voltage from drain electrode 111 to source/body electrode 112 by depletion of drift region 102 via reverse-biased junctions with P-type substrate 101 and with P-type body region 103. This device is not capable of supporting reverse voltage (source electrode 112 above drain electrode 111) because the junction between P-body 103 and drift region 102 becomes forward biased in this condition.

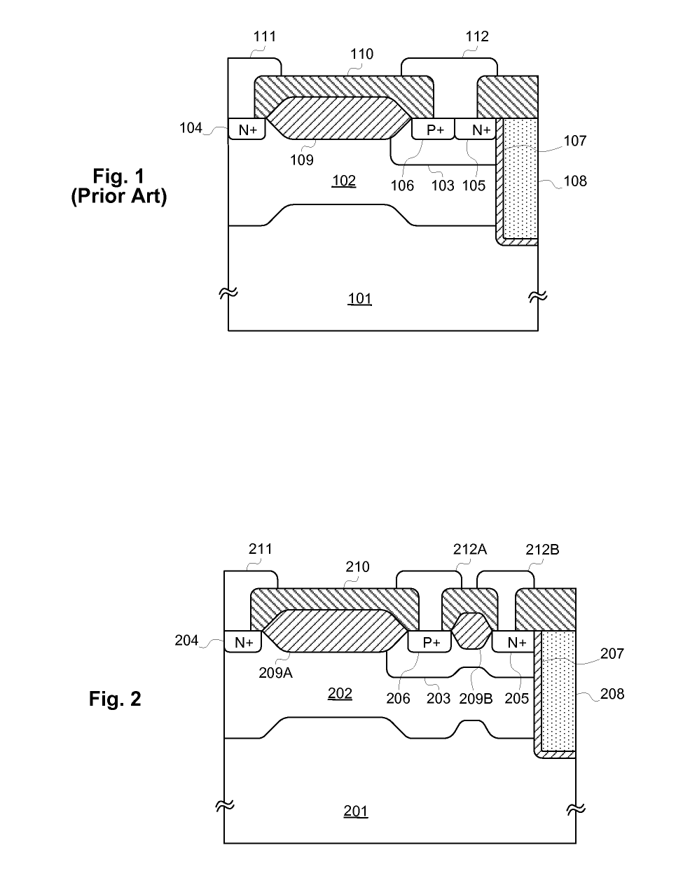

FIG. 2 shows the schematic cross-section of an LTDMOS according to one embodiment of the present invention. This structure is similar to the prior art LTDMOS of FIG. 1 in many respects, but in this device the P-body region 203 is elongated to allow a second field oxide region 209B to separate P+ body contact region 206 from N+ source region 205. This design change provides the important benefit of allowing this LTDMOS device to support a voltage from source electrode 212B to body electrode 212A and drain electrode 211. The maximum voltage that can be supported from drain 211 to body 212A and source 212B is determined by the length and doping of drift region 202, while the maximum voltage that can be supported from source 212B to body 212A is determined by the doping of P-body 203 and the distance from P+ 206 to N+ 205. In a preferred embodiment, the maximum drain-source voltage is much higher than the maximum source-drain voltage. For example, the former may be in the range of 20 to 60V while the latter is in the range of 5 to 10V.

One potential disadvantage of the separated body and source is that, if the source assumes a higher voltage than the body during normal on-state operation, the resulting back-bias will cause an increase in the threshold voltage, requiring a higher gate voltage to maintain a given on-state current. This may be particularly problematic in a source-follower mode of operation, in which the source voltage is driven to approximately the applied gate voltage minus the threshold voltage. In this case, the overdrive of the gate relative to the desire source voltage will be increased, which may lead to excessive stress on the gate dielectric. To mitigate this problem, one embodiment of this invention includes provision of a body voltage that is controlled to be different when the LTDMOS device is reverse blocking (body is tied to ground, or substrate voltage) than in the on-state (body is tied to source).

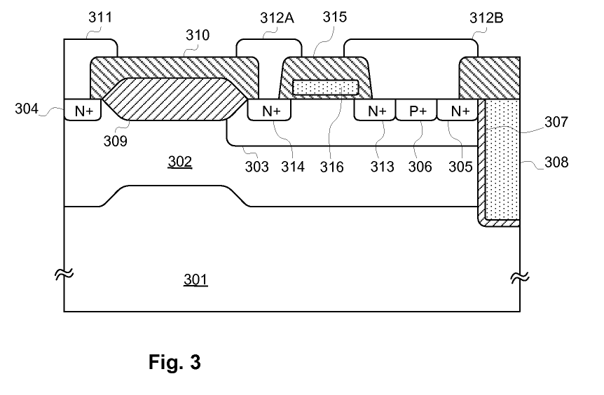

FIG. 3 shows another embodiment of an LTDMOS in accordance with the present invention. Unlike the device of FIG. 2, this device maintains a short between the body and source of the LTDMOS, thus avoiding the back-bias issue described above. To facilitate reverse blocking (source above drain), the LTDMOS of FIG. 3 incorporates a low-voltage NMOS device in series with the LTDMOS device. Compared to the equivalent elements of FIG. 1, this device has an elongated P-body region 303. The low-voltage NMOS transistor comprises NMOS drain 314, NMOS gate 316 overlying NMOS gate dielectric 315, and NMOS source 313. NMOS source 313 is electrically connected to heavily-doped P+ body contact region 306 and LTDMOS source 305 by electrode 312B. In a preferred embodiment, LTDMOS gate 308 and NMOS gate 316 are electrically connected a controlled by the same gate voltage.

In the forward blocking state, the gate voltage is held low, such that both the NMOS and LTDMOS devices are off. The voltage from drain electrode 311 to source electrode 312A is supported by the reverse-biased junctions of drift region 302 and P-body 303 and substrate 301. In the reverse blocking state, the gate voltage is also held low, and the voltage from source to drain is blocked by the reverse-biased junction of NMOS drain 314 and P-body 303. In the on-state, the gate voltage is high enough to exceed the threshold voltage and form—conduction channels beneath the NMOS gate 316 and adjacent the LTDMOS gate 308. Thus a continuous path exists for electron current to flow from NMOS drain through the NMOS channel to NMOS source 313, through intermediate electrode 312B to LTDMOS source 305, down through the LTDMOS channel, then laterally through drift region 302 to LTDMOS drain 304. Intermediate electrode may be left electrically floating, in which case it will assume the potential required for any of these modes of operation. Alternatively, an external circuit may be used to detect and/or set the voltage on intermediate electrode 312B.

What is claimed is:

1. A lateral trench DMOS device formed in a semiconductor substrate of a first conductivity type and comprising:
a trench extending downward from a surface of the substrate, the trench being lined with a dielectric layer and containing a gate electrode;
a source region of a second conductivity type opposite the first conductivity type adjacent the surface of the substrate and a sidewall of the trench;
a drain region of the second conductivity type adjacent the surface of the substrate and spaced apart from the source region;
a body region of the first conductivity type adjacent the source region and the sidewall of the trench;
a drift region of the second conductivity type adjacent the body region, the sidewall of the trench and the drain region; and
a body contact region of the first conductivity type disposed in the body region and spaced apart from the source region.

2. The lateral trench DMOS device of claim 1 wherein the substrate does not include an epitaxial layer.

3. The lateral trench DMOS device of claim 1 further comprising:
a first field dielectric region disposed at the surface of the substrate between the source region and the drain region; and
a second field dielectric region disposed at the surface of the substrate between the source region and the body contact region.

4. The lateral trench DMOS device of claim 1 further comprising:
a source electrode contacting the source region and a body electrode contacting the body contact region, the source electrode and body electrode electrically isolated from each other.

5. The lateral trench DMOS device of claim 1 where the length and doping of the drift region are selected so that that the maximum drain-to-source voltage is between twenty and sixty volts.

6. The lateral trench DMOS device of claim 1 where the doping of the P-body and the separation between the P+ body contact region and the N+ source region are selected so that that the maximum source-to-drain voltage is greater than five volts.

7. A lateral trench DMOS device formed in a semiconductor substrate of a first conductivity type and comprising:
a trench extending downward from a surface of the substrate, the trench being lined with a dielectric layer and containing a gate electrode;
a source region of a second conductivity type opposite the first conductivity type adjacent the surface of the substrate and a sidewall of the trench;
a drain region of the second conductivity type adjacent the surface of the substrate and spaced apart from the source region;
a body region of the first conductivity type adjacent the source region and the sidewall of the trench;
a drift region of the second conductivity type adjacent the body region, the sidewall of the trench and the drain region; and
an NMOS transistor comprising an NMOS source region and an NMOS drain region disposed in the body region and separated by an NMOS gate disposed above the surface of the substrate.

8. The lateral trench DMOS device of claim 5 wherein the substrate does not include an epitaxial layer.

9. The lateral trench DMOS device of claim 7 further comprising:
a drain electrode contacting the drain region;
a source electrode contacting the NMOS drain region; and
an intermediate electrode contacting the body region, the source region and the NMOS source region where the source, drain and intermediate electrodes are electrically isolated from each other.

10. The lateral trench DMOS device of claim 7 where the maximum drain-to-source voltage is between twenty and sixty volts and the maximum source-to-drain voltage is greater than five volts.
